(19) United States
(12) Patent Application Publication
(10) Pub. No.: US 2026/0136487 A1
(43) Pub. Date: May 14, 2026

(54) DYNAMIC AIR DIRECTION CONTROL

(71) Applicant: Intel Corporation, Santa Clara, CA (US)

(72) Inventor: Songlin ZHOU, Shanghai (CN)

(21) Appl. No.: 18/989,021

(22) Filed: Dec. 20, 2024

(30) Foreign Application Priority Data
Nov. 11, 2024 (WO) PCT/CN2024/131213

(51) Int. Cl. H05K 7/20; G06F 1/20

(52) U.S. Cl. CPC H05K 7/20145; G06F 1/206; H05K 7/20209

(57) ABSTRACT

A device, comprising a fan; a directional airflow shifter, configured to direct air from the fan within the device in either a first direction or a second direction; and a controller, configured to dynamically control the directional airflow shifter to direct the air from the fan in either the first direction or the second direction based on operational data.

### CROSS-REFERENCE TO RELATED APPLICATIONS

This application claims priority to International Application PCT/CN2024/131213, filed on Nov. 11, 2024, the entire contents of which are incorporated herein by reference.

### BACKGROUND

Electronic devices may include one or more heat generating elements, such as processors, memory, etc. In many configurations, it is desirable or even necessary to implement one or more cooling techniques, which may foster cooling of some or all of the heat generating elements. Many electronic devices include one or more fans, which may generate an air stream that is directed through a chamber in which one or more heat generating devices are located. The one or more fans may be started together, stopped together, increased in rotational velocity, or decreased in rotational velocity.

Traditional thermal capacity may only meet a thermal design power (TDP) of 22 W, whereas larger TDPs may be necessary. Many current consumer applications require, for example, a TDP of 25 W. It is therefore desired to create a cooling system that can support larger power demands.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the disclosed subject matter. In the following description, various exemplary embodiments of the disclosed subject matter are described with reference to the following drawings, in which:

FIG. 1 shows a conventional system configuration;

FIG. 2 depicts a directional airflow shifter to control fan airflow;

FIG. 3 depicts a first scenario;

FIG. 4 depicts a second scenario;

FIG. 5 depicts a third scenario;

FIG. 6 depicts a spring design to limit directional airflow shifter position; and

FIG. 7 depicts thermal test results;

FIG. 8 depicts a cost assessment of the device disclosed herein; and

FIG. 9 depicts a device.

### DESCRIPTION

The following detailed description refers to the accompanying drawings that show, by way of illustration, exemplary details and embodiments in which aspects of the embodiments may be practiced.

The word “exemplary” is used herein to mean “serving as an example, instance, or illustration”. Any embodiment or design described herein as “exemplary” is not necessarily to be construed as preferred or advantageous over other embodiments or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

As used herein, “memory” is understood as a computer-readable medium (e.g., a non-transitory computer-readable medium) in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, 3D XPoint™, among others, or any combination thereof. Registers, shift registers, processor registers, data buffers, among others, are also embraced herein by the term memory. The term “software” refers to any type of executable instruction, including firmware.

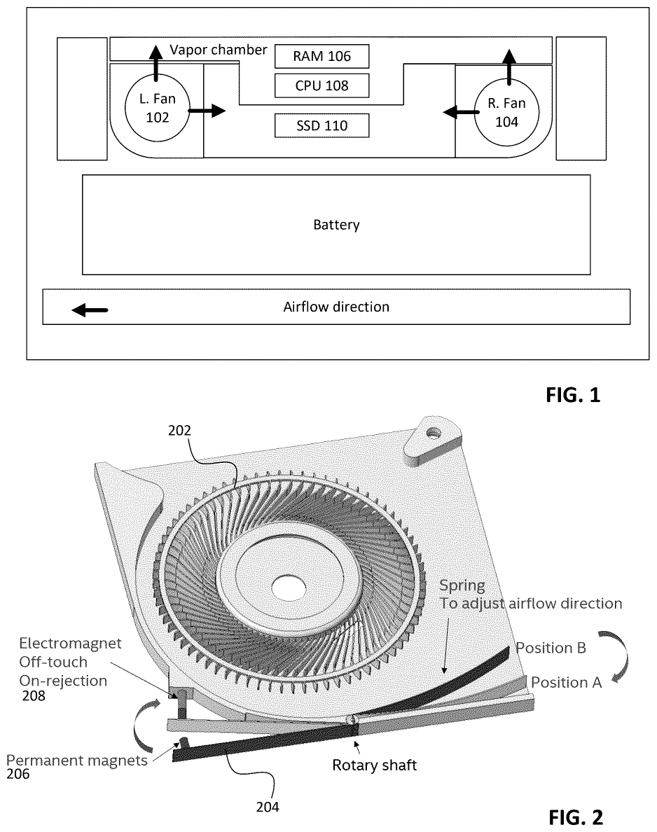

FIG. 1 depicts a conventional system in which one or two fans are present in a device to cool multiple components (e.g., a CPU and a memory, although any heat-producing device may be conceivable). The system may include one or more fans (two fans are depicted herein) 102 and 104. The fans may be placed in a vicinity of the multiple components. Illustratively, a random access memory (RAM) 106, a central processing unit (CPU) 108, and a solid state drive (SSD) memory 110 are depicted herein, although any plurality of heat-generating and/or heat-sensitive components is conceivable. One or more devices may be present to change the rotational velocity of the fans. No mechanism is available to change the direction of the airflow or to target the airflow direction based on sensor data. That is, the conventional approach is to turn all of the one or more fans on together or off together, or, otherwise stated, to change the rotational velocity of all fans present, whether to zero rotational velocity, a maximum rotational velocity, or some rotational velocity in-between. Moreover, the cooling mechanism conventionally does not permit directional changes in the airflow (e.g., is built without a means to change a direction of the airflow).

In the following, an airflow guiding structure is described that provides reduced energy hedging and that can support TDP 25 W or beyond. The components may be or include, for example, an SSD and a processor (e.g., a CPU), although, the concepts disclosed herein are applicable to any heat-producing components. When the load on a first component (e.g., illustratively, an SSD) is sufficiently great, the first component may reach a temperature (e.g., a skin temperature, a surface temperature) beyond its allowable or desired maximum (e.g., beyond its specification). Alternatively or additionally, a second component (e.g., illustratively, a CPU) may exceed its allowable maximum temperature, depending on its load.

It may not be possible to meet the thermal requirements of all heat parts (e.g., of all components, of the first component and the second component) in all user scenarios through only one thermal solution. The principles and methods disclosed herein will therefore focus on how to provide a thermal solution that can be dynamically adjusted to selectively target one or more of multiple heat sources within different use scenarios.

Conventionally it is known to increase fan speed to improve the cooling capability of the system. It is also known to increase the amount of thermal spreading material (e.g., copper foil and/or graphite sheets) at hot spots. These approaches may be, however, disadvantageous because increasing the fan speed increases the acoustic level, which may reduce utility or otherwise violate customer specifications or desires, and because the addition of thermal spreading material increases overall costs.

An underlying concept of the principles and methods disclosed herein is to design a directional airflow shifter (also referred to herein as a spring, or also a device) to dynamically adjust the airflow direction of the fan. FIG. 2 depicts a directional airflow shifter to control fan airflow. In this figure, a fan 202 is depicted in a housing. A directional airflow shifter 204 is mounted on a rotary shaft such that it has at least two positions. The directional airflow shifter may be made of any material that is suitable for its purpose, which may include, as non-limiting examples, stainless steel or steel. The directional airflow shifter may be manufactured by cutting, laser cutting, stamping, or otherwise. The directional airflow shifter 204 may include a magnet 206 (e.g., a permanent magnet). The housing may include an electromagnet 208. The electromagnet may be inexpensively manufactured using any known technique.

The polarities may be selected such that the permanent magnet 206 attracts to the housing and/or to a portion of the electromagnet 208 when the electromagnet 208 is turned off. If the electromagnet 208 is switched on, the resulting polarity of the electromagnet 208 may be identical to a portion of the permanent magnet 206 (e.g., a portion that makes contact with the electromagnet) such that the electromagnet 208 repels the permanent magnet 206. Otherwise stated, the directional airflow shifter 204 may be in a first position (e.g., connected to the electromagnet) when the electromagnet 208 is switched off and in a second position (e.g., repelled away from the electromagnet) when the electromagnet 208 is switched on. In this manner, and using the combination of the electromagnet 208 and the permanent magnet assembly 206, the position of the directional airflow shifter 204 (e.g. one magnet per spring; one magnet per directional airflow shifter) may be controlled.

When the electromagnet is off, the permanent magnets on the spring may attract to the electromagnet's core, and the directional airflow shifter will be pulled over, so that the directional airflow shifter is in position A. When the electromagnet is on, a repelling force may be generated that may push the directional airflow shifter away so that the directional airflow shifter is in position B. The fans may have different wind directions when the directional airflow shifter is in position A as opposed to position B.

It is expressly noted that the above configuration is merely one possible configuration among many options. For example, although the electromagnet 206 is disclosed above as being located in the housing, and the permanent magnet is disclosed above as being located on the directional airflow shifter, these locations may optionally be configured in opposite locations, such that the electromagnet is on the directional airflow shifter, and the permanent magnet is on the housing. Alternatively or additionally, the directional airflow shifter may be configured to include a mechanical force, such as a spring, to keep the directional airflow shifter in one position (e.g., position A or position B), and wherein turning on the electromagnet creates a force that is sufficient to overcome the mechanical force and thereby move the directional airflow shifter into the opposite position.

At least three scenarios exist for controlling the electromagnet.

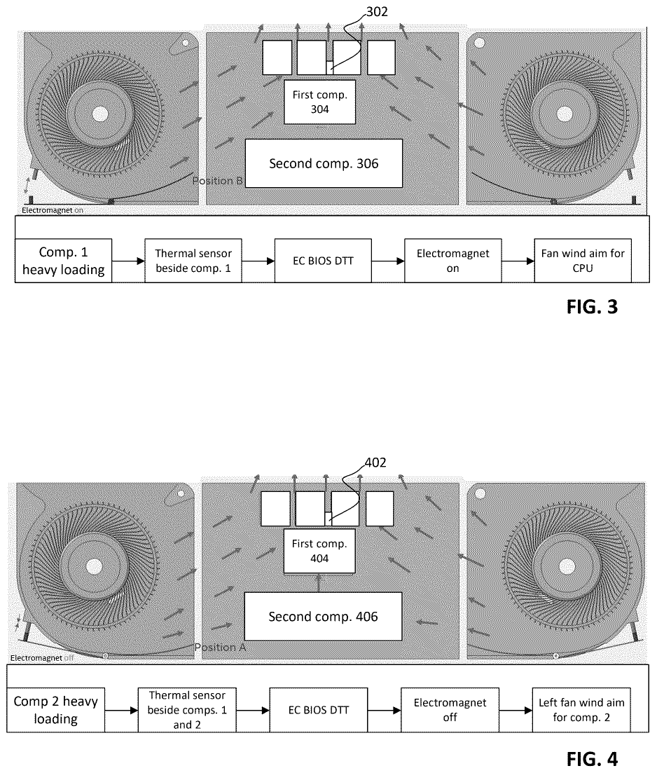

FIG. 3 depicts a first scenario, in which a first component 304 (e.g., a CPU) is loaded. In this figure, a thermal sensor 302 (e.g. thermometer, any device capable of generating sensor data to represent a temperature) is placed beside the first component 304 or a second component 306 (e.g., an SSD or other device) (or placed in such a manner as to generate sensor data that represent a temperature of the first component or second component). If the first component 304 is heavily loaded, the first component's temperature will increase. If the DTT and BIOS determine that thermal sensor temperature exceeds the setting value (e.g., if the temperature is outside of a predetermined range), the controller may trigger the electromagnet to turn on, which may cause the directional airflow shifter to move from position A to position B, thereby aiming the air toward the first component 304.

FIG. 4 depicts a second scenario, in which a device includes a first component 404 (e.g., a CPU) and a second component 406 (e.g., an SSD), and wherein the second component 406 is loaded. A thermal sensor 402 is placed beside in close proximity to the second component 406. If the second component is heavily loaded, the thermal sensor for the second component temperature will increase. If the DTT and BIOS determine that thermal sensor temperature exceeds the setting value (e.g., the temperature is outside of a predetermined range), the controller will trigger the electromagnet to turn off, thereby causing the spring to change to position A, and thus aiming the fan's wind (e.g. the air moved by the fan) toward the second component.

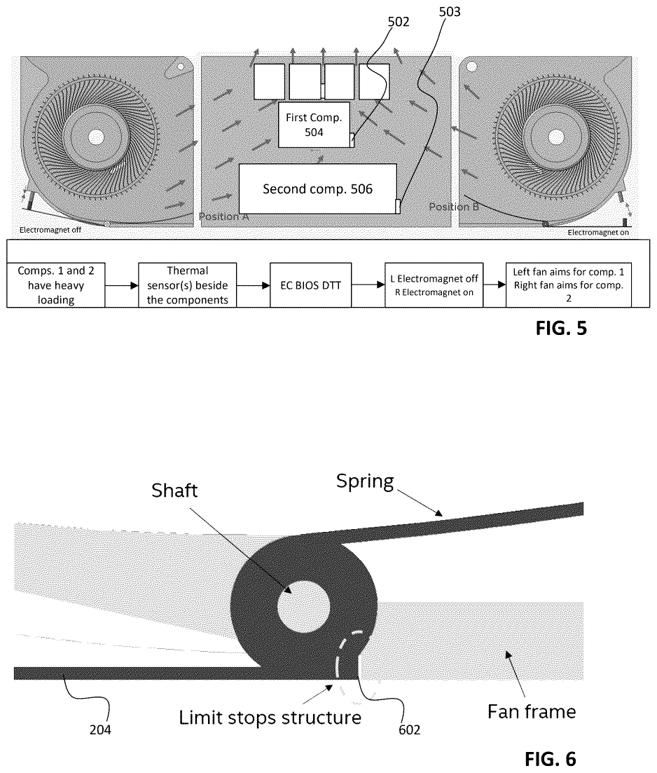

FIG. 5 depicts a third scenario in which both a first component 504 (e.g., a CPU) and a second component 506 (e.g. an SSD) are loaded. Notably, the prior examples were given in instances in which a joint sensor (e.g., a thermal sensor for 2 or more components) was used. It should be noted that multiple sensors akin to the configuration that will be described with respect to FIG. 5 may be optionally used for the configurations described with respect to FIG. 3 or FIG. 4. With respect to FIG. 5, the device may include a first thermal sensor 502 and a second thermal sensor 503. In some configurations, it may be desirable for the first sensor 502 to be located such that it may detect a temperature of the first component 504, and for the second sensor 503 to be located such that it may detect a temperature of the second component 506. If the first component 504 and the second component 506 are both loaded, the first component 504 temperature and the second component 506 temperature (e.g., as measured by the first thermal sensor 502 and the second thermal sensor 503, respectively) will increase.

The DTT and BIOS may monitor the thermal sensor data to determine whether the temperature of the first component 504 is outside of a first range and/or the temperature of the second component 506 is outside of a second range. If the DTT and BIOS determine that thermal sensor 502 temperatures exceed the setting value (e.g., if both temperatures are outside of a predetermined range, or if the first temperature is outside of the first predetermined range and the other temperature is outside of the second predetermined range), the controller may trigger each of the left electromagnet (e.g. one electromagnet) and the right electromagnet (e.g., the other electromagnet) to turn on. In this manner, the left spring will be in position A, and the right spring will be in position A. As depicted herein, position A may correspond to an airflow directed to both the first component and the second component, whereas position B may correspond only to airflow directed only to the first component. Thus, both the air from the left fan and the air from the second fan will be directed toward the second component 506.

It is expressly noted that a variety of configurations are possible. These various configurations will depend at least on the physical configurations of the directional airflow shifter, the locations of the first component and the second component, the expected heat production of the first component relative to the second component, the maximum acceptable temperate of the first component and/or the second component. For clarity, at least the following configurations will now be expressly disclosed.

| Option | Position A | Position B |
|---|---|---|
| 1 | Directed to first | Directed to second component |
| | component | |
| 2 | Directed to both first | Directed to first component |
| | component and second | |
| | component | |
| 3 | Directed to both first | Directed to second component |
| | component and second | |
| | component | |
| 4 | Directed to first | Directed to both first |
| | component | component and second component |
| 5 | Directed to second | Directed to both first |
| | component | component and second component |
| 6 | Directed to second | Directed to first component |
| | component | |

As can be seen, many configurations are possible.

Different fans may aim toward different heat sources. For example, and returning to FIG. 2, the device may be configured to select one of two positions of the directional airflow shifter 204 (e.g., using again the nomenclature of position A and position B). As shown in FIG. 2, and when the electromagnet is off, and thus the permanent magnets on the directional airflow shifter attract the electromagnet core, position A is fixed. In position B, the electromagnet is engaged, and the directional airflow shifter is repelled from the electromagnet.

FIG. 6 depicts a portion of the directional airflow shifter using a position delimiter. The directional airflow shifter can be designed to limit stops to control the spring position to prevent the spring from striking the fan blade. In this exemplary configuration, the directional airflow shifter 204 is being repelled by the electromagnet into position B. In order to have a consistent fixed point for position B, the device may include a stop 602. In this case, the stop 602 is an extension around a fulcrum of the directional airflow shifter 204, which, when in position B, abuts the fan frame and precludes further movement in a rotational direction. It is expressly noted that the use of this fulcrum is merely one embodiment of a position delimiter that is conceivable for the purposes disclosed herein, and the skilled person may select any other configuration for this purpose.

This device disclosed herein can meet design targets of TDP 25 W, whereas traditional designs can only support TDP 22 W (e.g., the design disclosed herein can include the TDP by at least 3 W). The device disclosed herein may selectively direct airflow to one or more devices that have exceeded an allowable temperature or are otherwise in need of cooling.

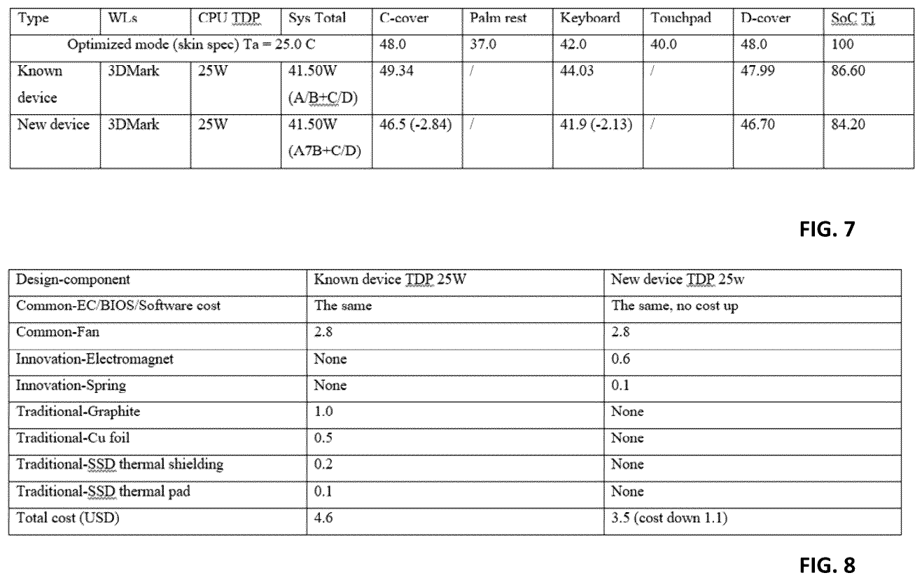

FIG. 7 depicts thermal test results that show the effectiveness of the device disclosed herein relative to CPU loading. As shown, the design improved C-cover skin temperature by 2.84° C., and KB skin temperature by 2.13° C. These reduced skin temperatures may meet customer and internal specifications. The device disclosed herein can support 25 W TDP, which represents a significant improvement in thermal management over the conventional solutions.

Moreover, the device as disclosed herein may be less expensive than known cooling solutions, which may instead utilize additional materials such as graphite and copper foil to control temperature. FIG. 8 depicts a cost assessment of the device disclosed herein as compared to a conventional configuration. It can be seen from FIG. 8, that the device as disclosed herein may cost approximately $1.10 USD less than a conventional device for controlling temperature that uses copper and graphite, and which requires thermal shielding and thermal padding.

Due to dynamic control, the ideal wind direction may be different for each of the various heat sources. As such, the temperature of the D cover graphite and/or Cu foil and/or the SSD thermal shielding and pad can be reduced.

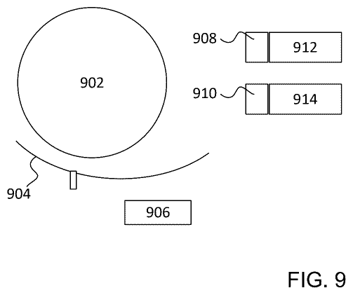

FIG. 9 depicts a device that includes a fan 902, which may generate an air flow that may be used to cool one or more components. The device may include a directional airflow shifter 904, which may be configured to selectively direct air from the fan within the device in either a first direction or a second direction. The device may include a controller 906, which may be configured to dynamically control the directional airflow shifter to direct the air from the fan in either the first direction or the second direction based on operational data. In this manner, the operational data may include sensor data. The sensor data may be or include data from a first thermal sensor 908 and/or a second thermal sensor 910. The first sensor data may represent a temperature of a first electronic component 912, and the second sensor data may represent a temperature of a second electronic component 914. The controller 906 may be configured to dynamically control the directional airflow shifter 904 to direct the air from the fan 902 in the first direction when the temperature of the first electronic component 912 is within a range and to control the directional airflow shifter to direct the air from the fan in the second direction when the temperature of the first electronic component is outside the range. As stated herein above, there is considerable flexibility in the configuration of this device, and it is expressly noted that the first thermal sensor 908 is depicted as being close to or attached to the first component 912, but it could be located elsewhere, or could even be located in close proximity to the second component 914 so as to primarily measure a temperature of the second component 914 rather than the first component 912, or even to measure a combined temperature of the first component 912 and the second component 914.

In this manner, the operational data may be or include sensor data from one or more thermal sensors (e.g., 908 and/or 910) representing a temperature of the first electric component and/or the second electronic component, and wherein the controller is configured to control the electromagnet to operate in the first operational mode when the temperature of the second electronic component is within a range and to operate in a second operational mode when the temperature of the second electronic component is outside of the range.

In an alternative configuration, the operational data may be or include data indicating a workflow of a first device or a second device. In this configuration, the workflow data are a proxy for a temperature of the first device or a second device (e.g., the greater the processing demand, the greater the temperature). In this manner, the workflow data may be used instead of thermal sensor data, or in conjunction with the thermal sensor data. IN this manner, the controller may be configured to dynamically control the directional airflow shifter to direct the air from the fan in the first direction when the workflow of the first device satisfies a predetermined criterion, and wherein the controller is configured to dynamically control the directional airflow shifter to direct the air from the fan in the second direction when the workflow of the second device satisfies a predetermined criterion.

In the foregoing, the EC BIOS DTT, or the like have been disclosed as operating or controlling the positioning of the dynamic airflow shifter, such as by engaging or disengaging the electromagnet(s). This function may generally be performed by a controller. That is, the controller may be configured to receive sensor data from the one or more thermal sensors, and based on these sensor data, it may selectively operate the electromagnets to cause the directional airflow shifter to change positions in the manner described above. The controller may be any processor, microprocessor, integrated circuit, system on chip, or the like, which may be capable of receiving or evaluating sensor data and causing the electromagnets to activate or deactivate.

Although the change of positions of the directional airflow shifter has been described above with respect to the use of permanent magnets and electromagnets, the positions may be switched using any other suitable mechanism to change positions. For example, the directional airflow shifter(s) may alternatively be connected to one or more motors, and the controller may selectively cause the one or more motors to operate in a first direction or a second direction, depending on the thermal sensor data, such that the directional airflow shifter is changed from a first position to a second position or vice versa.

While the above descriptions and connected figures may depict components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc.

Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

In the following, additional aspects will be disclosed by way of Example:

In Example 1, a device, including a fan; a directional airflow shifter, configured to direct air from the fan within the device in either a first direction or a second direction; and a controller, configured to dynamically control the directional airflow shifter to direct the air from the fan in either the first direction or the second direction based on operational data.

In Example 2, the device of Example 1, wherein the operational data include sensor data representing a temperature of the first electronic component, and wherein the controller is configured to dynamically control the directional airflow shifter to direct the air from the fan in the first direction when the temperature of the first electronic component is within a range and to control the directional airflow shifter to direct the air from the fan in the second direction when the temperature of the first electronic component is outside the range.

In Example 3, the device of Example 1 or 2, wherein the operational data include sensor data representing a temperature of the second electronic component, and wherein the controller is configured to control the electromagnet to operate in the first operational mode when the temperature of the second electronic component is within a range and to operate in a second operational mode when the temperature of the second electronic component is outside of the range.

In Example 4, the device of Example 1, wherein the operational data include data indicating a workflow of a first device or a second device, and wherein the controller is configured to dynamically control the directional airflow shifter to direct the air from the fan in the first direction when the workflow of the first device satisfies a predetermined criterion, and wherein the controller is configured to dynamically control the directional airflow shifter to direct the air from the fan in the second direction when the workflow of the second device satisfies a predetermined criterion.

In Example 5, the device of Example 4, wherein the first device is a processor and the second device is a memory.

In Example 6, a device, including: a fan; a directional airflow shifter, including: a first portion, including a permanent magnet; a second portion; a fulcrum, between the first portion and the second portion; an electromagnet; and a controller, configured to control the electromagnet to alternate between a first operational mode and a second operational mode based on operational data.

In Example 7, the device of Example 6, wherein the permanent magnet is configured to be a first distance from the electromagnet in the first operational mode; wherein the permanent magnet is configured to be a second distance from the electromagnet in the second operational mode; and wherein the first distance is smaller than the second distance.

In Example 8, the device of Example 7, wherein the controller is configured to turn the electromagnet off in the first operational mode, and wherein the permanent magnet is configured to attract to the electromagnet in the first operational mode.

In Example 9, the device of Example 7 or 8, wherein the second portion is configured to be a third distance from the fan in the first operational mode; wherein the second portion is configured to be a fourth distance from the fan in the second operational mode; and wherein the third distance is greater than the fourth distance.

In Example 10, the device of Example 7, wherein the electromagnet is configured to repel the permanent magnet in the second operational mode.

In Example 11, the device of Example 7 or 8, wherein the second portion is configured to be a third distance from the fan in the first operational mode; wherein the second portion is configured to be a fourth distance from the fan in the second operational mode; and wherein the third distance is greater than the fourth distance.

In Example 12, the device of any one of Examples 6 to 11, wherein the electromagnet is between the fan and the permanent magnet.

In Example 13, the device of any one of Examples 6 to 12, further including: a first electronic component; and a second electronic component; and wherein when the electromagnet is in the first operational mode, the directional airflow shifter is configured to direct more airflow of the fan to the first electronic component than to the second electronic component; and wherein when the electromagnet is in the second operational mode, the directional airflow shifter is configured to direct less airflow of the fan to the first electronic component than to the second electronic component.

In Example 14, the device of Example 13, wherein the operational data include

sensor data representing a temperature of the first electronic component, and wherein the controller is configured to control the electromagnet to operate in the first operational mode when the temperature of the first electronic component is within a range and to operate in a second operational mode when the temperature of the first electronic component is outside the range.

In Example 15, the device of Example 13, wherein the operational data include sensor data representing a temperature of the second electronic component, and wherein the controller is configured to control the electromagnet to operate in the first operational mode when the temperature of the second electronic component is within a range and to operate in a second operational mode when the temperature of the second electronic component is outside of the range.

In Example 16, the device of any one of Examples 6 to 15, wherein the fulcrum includes a limiting structure that defines a first position of the directional airflow shifter corresponding to the first operational mode or a second position of the directional airflow shifter corresponding to the second operational mode.

In Example 17, the device of any one of Examples 6 to 16; wherein the fan is a first fan; the directional airflow shifter is a first directional airflow shifter; the fulcrum is a first fulcrum; and the electromagnet is a first electromagnet; further including: a second fan; a second directional airflow shifter, including: a third portion, including a ferromagnetic portion; a fourth portion; a fulcrum, between the third portion and the fourth portion; and a second electromagnet; and wherein the controller is configured to control the first electromagnet to alternate between a first operational mode and a second operational mode based on operational data and to control the second electromagnet to alternate between the first operational mode and the second operational mode based on operational data.

In Example 18, the device of Example 17, wherein the operational data include first sensor data representing a temperature of a first component and second sensor data representing a temperature of a second component, and wherein the controller is configured to control the first electromagnet to operate in the first operational mode when the temperature of the first component is within a range and to operate in a second operational mode when the temperature of the first component is outside of the range.

In Example 19, the device of Example 18, wherein the controller is configured to control the second electromagnet to operate in the first operational mode when the temperature of the second component is within a range and to operate in a second operational mode when the temperature of the second component is outside of the range.

In Example 20, the device of Example 18, wherein the controller is configured to control the first electromagnet to operate in the first operational mode when the temperature of the first component is within a first range and to control the second electromagnet to operate in the second operational mode when the temperature of the second component is within a second range.

In Example 21, a device, including: a fan; a directional airflow shifter, for shifting a direction of airflow from the fan to a first component or a second component, the directional airflow shifter including: a first portion, including a ferromagnetic portion; a second portion; a fulcrum, between the first portion and the second portion; an electromagnet; and a controller for controlling the electromagnet to alternate between a first operational mode and a second operational mode based on operational data.

In Example 22, the device of Example 21, wherein the ferromagnetic portion is for being a first distance from the electromagnet in the first operational mode and for being a second distance from the electromagnet in the second operational mode; and wherein the first distance is smaller than the second distance.

In Example 23, the device of Example 22, wherein the electromagnet is for attracting the ferromagnetic portion in the first operational mode.

In Example 24, the device of Example 22 or 23, wherein the second portion is for being a third distance from the fan in the first operational mode and for being a fourth distance from the fan in the second operational mode; and wherein the third distance is greater than the fourth distance.

In Example 25, the device of Example 22, wherein the electromagnet for repelling the ferromagnetic portion in the second operational mode.

In Example 26, the device of Example 22 or 23, wherein the second portion for being a third distance from the fan in the first operational mode; wherein the second portion is for being a fourth distance from the fan in the second operational mode; and wherein the third distance is greater than the fourth distance.

In Example 27, the device of any one of Examples 21 to 26, wherein the electromagnet is between the fan and the ferromagnetic portion.

In Example 28, the device of any one of Examples 21 to 27, further including: a first electronic component; and a second electronic component; and wherein when the electromagnet is in the first operational mode, the directional airflow shifter is for directing more airflow of the fan to the first electronic component than to the second electronic component; and wherein when the electromagnet is in the second operational mode, the directional airflow shifter is for directing less airflow of the fan to the first electronic component than to the second electronic component.

In Example 29, the device of Example 28, wherein the operational data include sensor data representing a temperature of the first component, and wherein the controller is configured for controlling the electromagnet to operate in the first operational mode when the temperature of the first component is within a range and to for controlling the electromagnetic to operate in a second operational mode when the temperature of the first component is outside of the range.

In Example 30, the device of Example 28, wherein the operational data include sensor data representing a temperature of the second component, and wherein the controller is configured to control the electromagnet to operate in the first operational mode when the temperature of the second component is within a range and to operate in a second operational mode when the temperature of the second component is outside of the range.

In Example 31, the device of any one of Examples 21 to 30, wherein the fulcrum includes a limiting structure that defines a first position of the directional airflow shifter corresponding to the first operational mode or a second position of the directional airflow shifter corresponding to the second operational mode.

In Example 32, the device of any one of Examples 21 to 31; wherein the fan is a first fan; the directional airflow shifter is a first directional airflow shifter; the fulcrum is a first fulcrum; and the electromagnet is a first electromagnet; further including: a second fan; a second directional airflow shifter, including: a third portion, including a ferromagnetic portion; a fourth portion; a fulcrum, between the third portion and the fourth portion; and a second electromagnet; and wherein the controller is for controlling the first electromagnet to alternate between a first operational mode and a second operational mode based on operational data and for controlling the second electromagnet to alternate between the first operational mode and the second operational mode based on operational data.

In Example 33, the device of Example 32, wherein the operational data include first sensor data representing a temperature of the first component and second sensor data representing a temperature of the second component, and wherein the controller is for controlling the first electromagnet to operate in the first operational mode when the temperature of the first component is within a range and for controlling the first electromagnet to operate in a second operational mode when the temperature of the first component is outside of the range.

In Example 34, the device of Example 33, wherein the controller is for controlling the second electromagnet to operate in the first operational mode when the temperature of the second component is within a range and for controlling the second electromagnet to operate in a second operational mode when the temperature of the second component is outside of the range.

In Example 35, the device of Example 33, wherein the controller is for controlling the first electromagnet to operate in the first operational mode when the temperature of the first component is within a first range and to for controlling the second electromagnet to operate in the second operational mode when the temperature of the second component is within a second range.

In Example 36, a non-transitory computer readable medium, including instructions, which if executed by a controller, cause the controller to control an electromagnet to alternate between a first operational mode and a second operational mode based on operational data; and wherein the first operational mode includes a first position of a directional airflow shifter relative to a fan, and the second operational mode includes a second position of the directional airflow shifter relative to the fan.

In Example 37, the non-transitory computer readable medium of Example 36, wherein the electromagnet is configured to attract a permanent magnet in the first operational mode.

In Example 38, the non-transitory computer readable medium of Example 36 or 37, wherein the electromagnet is configured to repel a permanent magnet in the second operational mode.

In Example 39, the non-transitory computer readable medium of Example 36, wherein the operational data include sensor data representing a temperature of a first component, and wherein the instructions are configured to cause the controller to control the electromagnet to operate in the first operational mode when the temperature of the first component is within a range and to operate in a second operational mode when the temperature of the first component is outside of the range.

In Example 40, the non-transitory computer readable medium of Example 38, wherein the operational data include sensor data representing a temperature of a second component, and wherein the instructions are configured to cause the controller to control the electromagnet to operate in the first operational mode when the temperature of the second component is within a range and to operate in a second operational mode when the temperature of the second component is outside of the range.

In Example 41, a method, including: directing air from the fan within the device in either a first direction or a second direction; and dynamically controlling the directional airflow shifter to direct the air from the fan in either the first direction or the second direction based on operational data.

In Example 42, the method of Example 41, wherein the operational data include sensor data representing a temperature of the first electronic component, and further including dynamically controlling the directional airflow shifter to direct the air from the fan in the first direction when the temperature of the first electronic component is within a range and controlling the directional airflow shifter to direct the air from the fan in the second direction when the temperature of the first electronic component is outside the range.

In Example 43, the method of Example 41 or 42, wherein the operational data include sensor data representing a temperature of the second electronic component; further including controlling the electromagnet to operate in the first operational mode when the temperature of the second electronic component is within a range and operating in a second operational mode when the temperature of the second electronic component is outside of the range.

In Example 44, the method of Example 41, wherein the operational data include data indicating a workflow of a first device or a second device; and further including dynamically controlling the directional airflow shifter to direct the air from the fan in the first direction when the workflow of the first device satisfies a predetermined criterion, and dynamically controlling the directional airflow shifter to direct the air from the fan in the second direction when the workflow of the second device satisfies a predetermined criterion.

In Example 45, the method of Example 44, wherein the first device is a processor and the second device is a memory.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1. A computing device, comprising:
a fan;
a directional airflow shifter, configured to direct air from the fan within the computing device in either a first direction or a second direction; and
a controller, configured to dynamically control the directional airflow shifter to direct the air from the fan in either the first direction or the second direction based on operational data.

2. The computing device of claim 1, wherein the operational data comprise sensor data representing a temperature of a first electronic component, and wherein the controller is configured to dynamically control the directional airflow shifter to direct the air from the fan in the first direction when the temperature of the first electronic component is within a range and to control the directional airflow shifter to direct the air from the fan in the second direction when the temperature of the first electronic component is outside the range.

3. The computing device of claim 1, wherein the operational data comprise sensor data representing a temperature of a second electronic component, and wherein the controller is configured to control an electromagnet to operate in the first operational mode when the temperature of the second electronic component is within a range and to operate in a second operational mode when the temperature of the second electronic component is outside of the range.

4. The computing device of claim 1, wherein the operational data comprise data indicating a workflow of a first device or a second device, and wherein the controller is configured to dynamically control the directional airflow shifter to direct the air from the fan in the first direction when the workflow of the first device satisfies a predetermined criterion, and wherein the controller is configured to dynamically control the directional airflow shifter to direct the air from the fan in the second direction when the workflow of the second device satisfies a predetermined criterion.

5. The computing device of claim 4, wherein the first device is a processor and the second device is a memory.

6. An apparatus, comprising:
a fan;
a directional airflow shifter, comprising:
a first portion, comprising a permanent magnet;
a second portion;
a fulcrum, between the first portion and the second portion;
an electromagnet, configured to attract or repel the permanent magnet; and
a controller, configured to control the electromagnet to alternate between a first operational mode and a second operational mode based on operational data.

7. The apparatus of claim 6, wherein the permanent magnet is configured to be a first distance from the electromagnet in the first operational mode; wherein the permanent magnet is configured to be a second distance from the electromagnet in the second operational mode; and wherein the first distance is smaller than the second distance.

8. The apparatus of claim 7, wherein the controller is configured to turn the electromagnet off in the first operational mode, and wherein the permanent magnet is configured to attract to the electromagnet in the first operational mode.

9. The apparatus of claim 7, wherein the second portion is configured to be a third distance from the fan in the first operational mode; wherein the second portion is configured to be a fourth distance from the fan in the second operational mode; and wherein the third distance is greater than the fourth distance.

10. The apparatus of claim 7, wherein the electromagnet is configured to repel the permanent magnet in the second operational mode.

11. The apparatus of claim 7, wherein the second portion is configured to be a third distance from the fan in the first operational mode; wherein the second portion is configured to be a fourth distance from the fan in the second operational mode; and wherein the third distance is greater than the fourth distance.

12. The apparatus of claim 6, wherein the electromagnet is disposed between the fan and the permanent magnet.

13. The apparatus of claim 6, further comprising:
a first electronic component; and
a second electronic component; and
wherein when the electromagnet is in the first operational mode, the directional airflow shifter is configured to direct more airflow of the fan to the first electronic component than to the second electronic component; and wherein when the electromagnet is in the second operational mode, the directional airflow shifter is configured to direct less airflow of the fan to the first electronic component than to the second electronic component.

14. The apparatus of claim 13, wherein the operational data comprise sensor data representing a temperature of the first electronic component, and wherein the controller is configured to control the electromagnet to operate in the first operational mode when the temperature of the first electronic component is within a range and to operate in a second operational mode when the temperature of the first electronic component is outside the range; or
wherein the operational data comprise sensor data representing a temperature of the second electronic component, and wherein the controller is configured to control the electromagnet to operate in the first operational mode when the temperature of the second electronic component is within a range and to operate in a second operational mode when the temperature of the second electronic component is outside of the range.

15. The apparatus of claim 6, wherein the fulcrum comprises a limiting structure that defines a first position of the directional airflow shifter corresponding to the first operational mode or a second position of the directional airflow shifter corresponding to the second operational mode.

16. The apparatus of claim 6;
wherein the fan is a first fan; the directional airflow shifter is a first directional airflow shifter; the fulcrum is a first fulcrum; and the electromagnet is a first electromagnet;
further comprising:
a second fan;
a second directional airflow shifter, comprising:
a third portion, comprising a ferromagnetic portion;
a fourth portion;
a fulcrum, between the third portion and the fourth portion; and
a second electromagnet; and
wherein the controller is configured to control the first electromagnet to alternate between a first operational mode and a second operational mode based on operational data and to control the second electromagnet to alternate between the first operational mode and the second operational mode based on operational data.

17. The apparatus of claim 16, wherein the operational data comprise first sensor data representing a temperature of a first component and second sensor data representing a temperature of a second component, and wherein the controller is configured to control the first electromagnet to operate in the first operational mode when the temperature of the first component is within a range and to operate in a second operational mode when the temperature of the first component is outside of the range.

18. The apparatus of claim 17, wherein the controller is configured to control the second electromagnet to operate in the first operational mode when the temperature of the second component is within a range and to operate in a second operational mode when the temperature of the second component is outside of the range; or wherein the controller is configured to control the first electromagnet to operate in the first operational mode when the temperature of the first component is within a first range and to control the second electromagnet to operate in the second operational mode when the temperature of the second component is within a second range.

19. The apparatus of claim 6, wherein the apparatus is provided in at least one of an integrated circuit, a System on Chip, a System in Package or a computing device.

20. A non-transitory computer readable medium, including instructions, which if executed by a controller, cause the controller to control an electromagnet to alternate between a first operational mode and a second operational mode based on operational data; and wherein the first operational mode includes a first position of a directional airflow shifter of a computing device relative to a fan, and the second operational mode includes a second position of the directional airflow shifter of a computer device relative to the fan.
